(19) United States
(12) Patent Application Publication
(10) Pub. No.: US 2026/0190335 A1
(43) Pub. Date: Jul. 2, 2026

(54) 3D NON-VOLATILE MEMORY DEVICE AND METHOD OF MANUFACTURING THE SAME

(71) Applicants: SK hynix Inc., Icheon-si (KR); EWHA UNIVERSITY - INDUSTRY COLLABORATION FOUNDATION, Seoul (KR)

(72) Inventors: Seongjae CHO, Seoul (KR); Soomin Kim, Seoul (KR)

(21) Appl. No.: 19/434,795

(22) Filed: Dec. 29, 2025

(30) Foreign Application Priority Data
Dec. 31, 2024 (KR) 10-2024-0201619

(51) Int. Cl. H10B 41/27; H10B 41/10; H10B 41/35; H10B 43/10; H10B 43/27; H10B 43/35; H10D 64/01; H10D 64/66

(52) U.S. Cl. CPC H10B 41/27; H10B 41/10; H10B 41/35; H10B 43/10; H10B 43/27; H10B 43/35; H10D 64/01316; H10D 64/665

(57) ABSTRACT

A 3D non-volatile memory device and a method for manufacturing the same are disclosed. The disclosed 3D non-volatile memory device may include a vertically elongated core pillar on a substrate; a vertical channel layer surrounding the core pillar; an insulating layer surrounding the vertical channel layer; and a body contact layer formed between the core pillar and the vertical channel layer for dissipating floating charges in the vertical channel layer.

### CROSS-REFERENCES TO RELATED APPLICATION

The present application claims, under 35 U.S.C. § 119(a), the benefit of Korean Patent Application No. 10-2024-0201619, filed on Dec. 31, 2024 which is hereby incorporated by reference in its entirety.

### BACKGROUND

### 1. Field

The present disclosure relates to semiconductor memory, and more particularly to a 3D non-volatile memory device and a method of manufacturing the same.

### 2. Description of the Related Art

In general, semiconductor memory devices used to store data may be categorized into volatile memory devices and non-volatile memory devices. Non-volatile memory devices retain stored data even if the power supply is interrupted. Therefore, non-volatile memory devices are widely used in situations where power is not always available, is often interrupted, or requires low power usage, such as mobile phones, memory cards, and other applications, and flash memory devices that may be erased in batches are a typical example.

As electronic systems and appliances become smaller and lighter, the need for smaller cells is increasing, even for flash memory devices. In non-volatile memory devices, the gap between neighboring cells has become narrower due to the fine process technology, which has led to an increase in the interference phenomenon of electron leakage. To overcome this limitation, stacking cells arranged in a monolayer structure into a three-dimensional vertical structure is being introduced.

3D non-volatile memory devices have minimized interference between bit lines (BL) due to the vertical structure of the cells, and interference between word lines (WL) is also reduced by using insulators instead of floating gates, greatly improving the speed, lifetime, and power efficiency of the memory. However, compared to 2D non-volatile memory devices, 3D non-volatile memory devices are unable to resolve body contact, resulting in a decrease in operational reliability, and it is necessary to develop a technology that may improve reliability.

### SUMMARY

A technical challenge of the present disclosure is to provide a 3D non-volatile memory device that may resolve the incomplete self-boosting phenomenon caused in the unselected cells and the potential drop caused by tunneling.

Furthermore, a technical challenge of the present disclosure is to provide a method of fabricating a 3D non-volatile memory device that may prevent the memory operation of the 3D non-volatile memory device from being in a floating state, thereby improving the reliability of the operation.

The problems to be solved by the present disclosure are not limited to those mentioned above, and other problems not mentioned may be understood by those skilled in the art from the following description.

According to one embodiment of the present disclosure, there may be provided a 3D non-volatile memory device comprising a vertically elongated core pillar on a substrate; a vertical channel layer surrounding the core pillar; an insulating layer surrounding the vertical channel layer; and a body contact layer formed between the core pillar and the vertical channel layer, configured to dissipate a floating charge of the vertical channel layer.

The body contact layer is formed on an inner wall of the vertical channel layer and may comprise a metal or conductive semiconductor material having a work function greater than or equal to a work function of the vertical channel layer. The work function of the body contact layer may be greater than or equal to 4.6 eV. The metal may be at least one selected from the group consisting of titanium (Ti), copper (Cu), nickel (Ni), silver (Ag), molybdenum (Mo), osmium (Os), rhenium (Re), selenium (Se), tantalum (Ta), beryllium (Be), rhodium (Rh), zinc (Zn), cobalt (Co), iron (Fe), niobium (Nb), tellurium (Te), gold (Au), iridium (Ir), platinum (Pt), antimony (Sb), tungsten (W), and any one or more of their alloys or nitrides. The conductive semiconductor material is a semiconductor material doped with trivalent impurities, and the trivalent impurity doped semiconductor material may be p-type silicon. The p-type silicon has any one of monocrystalline, polycrystalline, or amorphous structure.

The floating charge in the vertical channel layer may be a charge stored in the floating gate by a program and released into the vertical channel layer via tunneling.

The body contact layer can be configured to dissipate charges accumulating in the vertical channel by band-to-band tunneling or trap-assisted tunneling, which prevents self-boosting behavior for memory cells coupled to non-selected bit lines when a program voltage is applied to word lines during a program operation.

The 3D memory device may further comprise a conductive pad covering an upper exposed surface of the core pillar and electrically conducting with the body contact layer. The conductive pad may be configured to supply different bias voltages during data write, data erase, or data read operations of the 3D non-volatile memory device.

According to another embodiment of the present disclosure, A method of manufacturing a 3D non-volatile memory device comprises: forming a film stack by alternately forming a plurality of interlayer insulating film layers and a plurality of conductive film layers over a substrate; forming a first opening vertically penetrating the film stack; forming an insulating layer for storing information on an inner sidewall of the first opening; forming a vertical channel pillar by filling the first opening with a material constituting a channel region so that the insulating layer is not exposed; forming a second opening smaller than the first opening in the vertical channel pillar to form a vertical channel layer; forming a body contact layer on an exposed surface of the vertical channel layer; and filling the second opening with a core material to form a core pillar.

The method may further include the step of forming a conductive pad covering an upper exposed surface of the core pillar and electrically coupled with the body contact layer. The step of forming the conductive pad may comprise filling a hole in the body contact layer and above the core pillar with a conductive material.

A first end face of the conductive pad may be in contact with a first end face of the body contact layer and a second end face of the conductive pad may be exposed to provide a contact region. The body contact layer may be at least one selected from the group consisting of titanium (Ti), copper (Cu), nickel (Ni), silver (Ag), molybdenum (Mo), osmium (Os), rhenium (Re), selenium (Se), tantalum (Ta), beryllium (Be), rhodium (Rh), zinc (Zn), cobalt (Co), iron (Fe), niobium (Nb), tellurium (Te), gold (Au), iridium (Ir), platinum (Pt), antimony (Sb), tungsten (W), and any one or more of their alloys or nitrides. The body contact layer may comprise p-type silicon.

The step of forming the body contact layer on the exposed surface of the channel layer may comprise any one of a conformal deposition process and an epitaxy process capable of in-situ doping.

The vertical channel layer may be coupled to the substrate.

Embodiments of the present disclosure may provide a 3D non-volatile memory device capable of addressing incomplete self-boosting and tunneling-induced potential drops in unselected cells by including a body contact layer formed on an inner wall of the channel layer, which exists between the vertical channel layer and the core pillar.

Furthermore, the technical challenges of the present disclosure may provide a method for manufacturing a 3D non-volatile memory device that may resolve the floating state of the channel layer by a metal or conductive semiconductor material having a work function in an acceptable range included in the body contact layer of the 3D non-volatile memory device, thereby preventing the memory operation from being performed in a floating state, thereby improving the operation reliability.

However, the effects of the present disclosure are not limited to the above effects, and may be expanded in various ways without departing from the technical ideas and scope of the present disclosure.

### BRIEF DESCRIPTION OF THE DRAWINGS

FIG. 1 illustrates a 3D non-volatile memory device according to one embodiment of the present disclosure.

FIG. 2A illustrates the structure of a three-dimensional non-volatile memory device including memory cells for implementing a memory cell array according to one embodiment of the present disclosure, FIG. 2B is a cross-sectional view illustrating the structure of the memory cells according to one embodiment, and FIG. 2C is an equivalent schematic illustrating the structure of the memory cells according to one embodiment.

FIGS. 3A through 3J sequentially illustrate a method of fabricating a 3D non-volatile memory device according to one embodiment of the present disclosure.

FIGS. 4A through 4D sequentially illustrate a method of preparing a substrate for a 3D non-volatile memory device according to one embodiment of the present disclosure.

FIGS. 5A and 5B illustrate the performance of a 3D non-volatile memory device according to one embodiment of the present disclosure.

FIG. 6 illustrates a bond between a body contact layer and a vertical channel layer, according to one embodiment of the present disclosure.

FIG. 7 illustrates a storage device comprising a solid-state disk according to one embodiment of the present disclosure.

FIG. 8 illustrates a memory system according to another embodiment of the present disclosure.

FIG. 9 illustrates a data storage device according to another embodiment of the present disclosure.

FIG. 10 illustrates a flash memory device and a computing system including the flash memory device, according to another embodiment of the present disclosure.

### DETAILED DESCRIPTION

Hereinafter, embodiments of the present disclosure will be described in detail with reference to the accompanying drawings.

The embodiments described below are provided to make the disclosure more clearer to those of ordinary skill in the art, and the scope of the disclosure is not limited by the following embodiments, and the following embodiments may be modified in various other forms.

The terms used herein are intended to describe specific embodiments and are not intended to limit the disclosure. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Further, as used herein, the term “connected” is intended to mean not only that certain elements are directly connected, but also that they are indirectly connected by the interposition of other elements between them.

Furthermore, when the present disclosure refers to a member being located “on” another member, this includes not only when a member abuts another member, but also when there is another member between the two members. As used herein, the term “and/or” includes any one of the enumerated items and any combination of one or more of them. In addition, the terms “about,” “substantially,” and the like as used herein are intended to mean at or near the range of values or degrees, taking into account inherent manufacturing and material tolerances, and to prevent infringers from taking unfair advantage of the disclosure where precise or absolute figures are provided for the purpose of illustration.

Embodiments of the present disclosure will now be described in detail with reference to the accompanying drawings. The sizes or thicknesses of the areas or parts shown in the accompanying drawings may be somewhat exaggerated for clarity and ease of description.

Throughout the detailed description, like reference numerals designate like components.

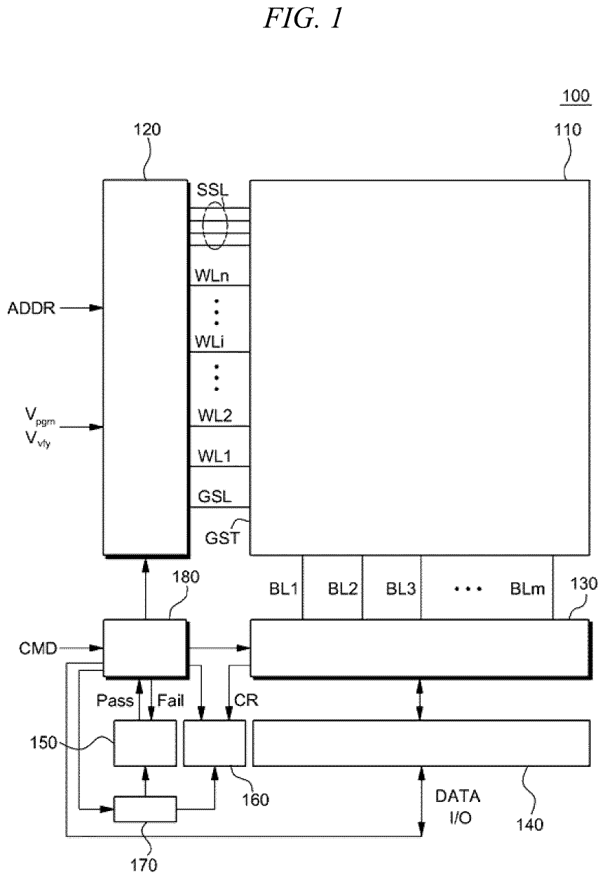

FIG. 1 is a block diagram illustrating a three-dimensional non-volatile memory device 100, according to one embodiment of the present disclosure.

Referring to FIG. 1, the three-dimensional non-volatile memory device (100) may include a memory cell array (110) of a plurality of memory cells, a row decoder (120), a read/write circuit 130, and a pillar decoder (140). The memory cell array (110) may be connected to the row decoder (120) via word lines (WL1, WL2, . . . , WLi, . . . , WLn), select lines SSL, and ground select lines GSL. Additionally, the memory cell array (110) may be connected to the read/write circuit (130) via bit lines (BL1, BL2, BL3, . . . , BLn).

If the three-dimensional non-volatile memory device (100) is a NAND Flash memory device, the memory cell array (110) may include memory cell strings (not shown) of a plurality of memory cells connected in series. At least two string-select transistors may be connected to one end of the memory cell strings, and a ground-select transistor may be connected to the other end of the memory cell strings. A common source line may be connected to the other end of the memory cell strings, and one of the ground select transistors may be electrically connected to the common source line. Word lines (WL1, WL2, . . . , WLi, . . . , WLn) may be connected to control gates of memory cells arranged along the pillar direction, respectively. The bit lines (BL1, BL2, BL3, . . . BLn) may be connected to a first end of the string select transistors.

The plurality of memory cells in the row direction having their control gate electrodes coupled to each of the word lines (WL1, WL2, . . . , WLi, . . . , WLn) constitute a logical page, and the number of the logical pages may be determined by the storage capacity of the memory cells. For example, depending on the storage level, a single-level cell memory storing 1 bit per memory cell, a multi-level cell (MLC) memory element storing 2 bits per memory cell, an 8LC memory element storing 3 bits per memory cell, and a 16LC memory element storing 4 bits per memory cell may be provided.

The memory cells of the memory cell array (110) may have the three-dimensional array structure described below parallel to the main plane of the semiconductor substrate. The memory cells comprising the page may be programmed in the same program cycle. For example, each memory cell connected to the first word line (WL1) may be programmed to the same program state (or target value) in the same program cycle, or to different program states. For example, in one program cycle, one memory cell may be programmed to program state (P1), another adjacent memory cell may be programmed to a second program state (P2), and yet another memory cell may be programmed to a third program state (P3). However, this is exemplary and embodiments are not limited thereto. In another embodiment, for a single-level cell with an interleaved architecture, the even and odd cells may comprise two different pages. For example, a 4 kB SLC device may have a word line of 65,536 memory cells. Also, in the case of multi-level cells, each cell stores one Least Significant Bit (LSB) and one Most Significant Bit (MSB), resulting in four pages. For example, in this case, the MSB and LSB pages may be provided on even bit lines and the MSB and LSB pages on odd bit lines.

The row decoder (120) may select a plurality of string select lines (SSLs) or may be voltage or current driven simultaneously. Additionally, the row decoder (120) may select any one of the word lines of the memory block. The row decoder (120) applies a word line voltage V_{WL} from a voltage generator (not shown) to the word lines of the selected memory block. In program operation, the row decoder (120) may apply a program voltage (V_{pgm}) and a verification voltage V_{vfy} to selected word lines (Selected WL) and a pass voltage (Vₚₐₛₛ) to unselected word lines (Unselected WL).

The memory cell array (110) may be addressed by bit lines (BL1, BL2, BL3, . . . , BLn) via a thermal decoder (140). The read/write circuitry (130) may receive externally communicated data via the thermal decoder (140) or may output data to the outside world.

The read/write circuit (130) may include a page buffer (not shown) and may operate as a sense amplifier or as a write driver, depending on the mode of operation. However, as used herein, read/write circuitry, or page buffer may be used interchangeably, in which case they should be understood interchangeably. For example, in a program operation, the read/write circuit (130) receives data from an external circuit and delivers bit line voltages corresponding to the data to be programmed into the bit lines of the cell array (110). In a read operation, the read/write circuit (130) may read out the data stored in the selected memory cell via the bit line, and may latch the read-out data and output it to the outside.

The read/write circuitry (130) may perform verification operations accompanying the program operation of the memory cell in response to a transmit signal transmitted from the control logic (180), and may output the verification read results as a page buffer signal a plurality of times in response to the transmit signal. In an embodiment, the read operation of the read/write circuit (130) may utilize charge integration using a bit line parasitic capacitor.

In an embodiment of the present disclosure, the programming of the memory cells on a page-by-page basis may be performed by an incremental step pulse programming (ISPP) algorithm. A verification algorithm for checking whether the threshold voltage Vₜₕ of the corresponding memory cell has reached the target voltage Vₜₕ level after the program pulse according to the ISPP algorithm may be coupled to the aforementioned bit lines and achieved by means of the current sensing circuitry. In one embodiment, the current sensing circuitry may be provided within the read/write circuit (130).

The control logic (180) may program the selected memory cells by executing program-verification loops according to an incremental step pulse programming (ISPP) mode. A success/failure verification circuit (150) verifies that the memory cell has reached the desired level each time the program loop count is incremented. If the memory cell has the desired threshold voltage, i.e., the target value, the program and program verification operations for the memory cell are terminated, as determined by the program pass, but if the memory cell has not reached the desired threshold voltage, as determined as the program fail, the success/failure verification circuit (150) may generate a count signal (not shown). The success/failure verification circuitry (150) may determine whether the program was successful and pass the result to control logic (180).

Control logic (180) may, in response to a command (CMD), control row decoder (120), read/write circuit (130), thermal decoder (140), success/failure detector (150), program loop sequence detector (160), and/or comparator (170) to perform pulse programming and verification operations in accordance with the ISPP method. Control logic (180) may determine whether to terminate or continue program operation by referencing a program success (Pass/Fail) communicated from pass/fail verification circuitry (150). Upon receiving a program Fail result from the pass/fail verification circuit (150), the control logic (180) may control the voltage generator (not shown) and page buffer (130) to generate V_{pgm} and V_{vfy} to advance a subsequent program loop. As such, the control logic (180) may receive a sequence of program loops in order to advance the program based on an increasing number of program loops. Conversely, when the control logic (180) is provided the result of a program pass, it may terminate program operation on the selected memory cells.

In various designs, the control logic (180) may be integrated within the same chip as the memory cell array (110) or may be disposed on a different chip, and embodiments of the present disclosure are not limited thereto. For example, as in a solid-state drive (SSD), the control logic (180) may be provided on a flash translation layer (FTL), which is a separate chip separated from the memory cell array (110).

Furthermore, while the success/failure verification circuitry (150), program loop sequence detector (160), and comparator (170) described above are illustrated as being formed separately from the control logic (180), embodiments are not limited thereto. For example, at least one of the success/failure verification circuitries (150), the program loop sequence detector (160), and the comparator (170) may be implemented software or hardware within the control logic (180). It will be appreciated that at least one of the success/failure verification circuitries (150), the program loop traversal detector (160), and the comparator (170) may be omitted or other circuit configurations may be added.

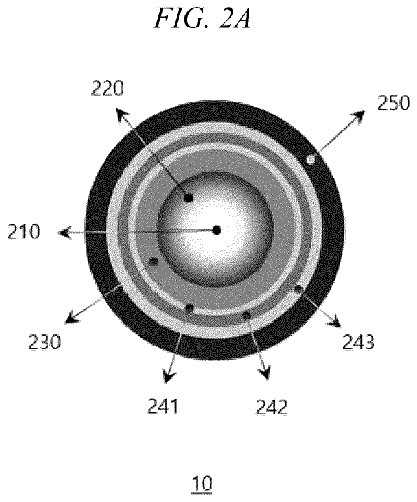

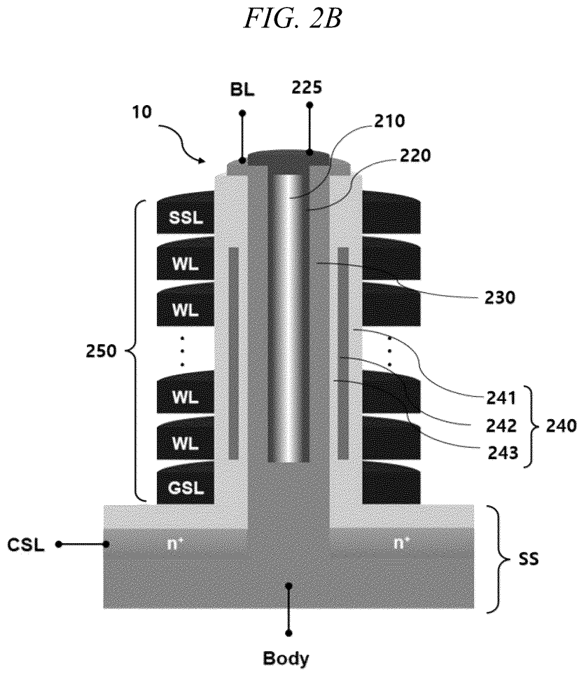

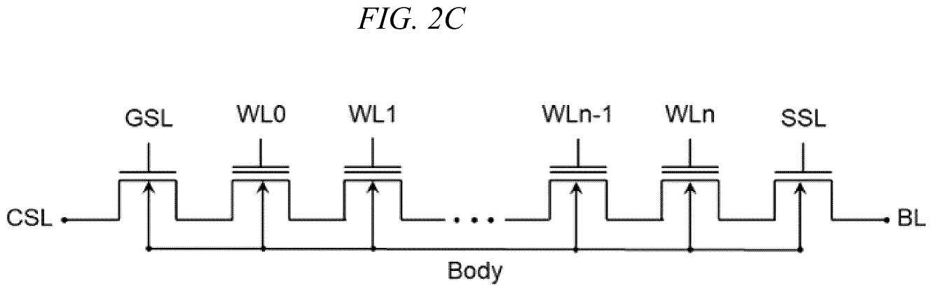

FIG. 2A is a plan view illustrating the structure of a three-dimensional non-volatile memory device comprising memory cells for implementing a memory cell array according to one embodiment of the present disclosure, FIG. 2B is a cross-sectional view illustrating the structure of a memory cell according to one embodiment, and FIG. 2C is an equivalent schematic illustrating the structure of a memory cell according to one embodiment. Although FIG. 2A exemplarily shows memory cells connected to one bit line, the present disclosure is not limited thereto and may be extended to an array of memory cells having M word lines on N bit lines.

Referring to FIGS. 2A and 2B, the 3D non-volatile memory device (10) may include a vertically elongated core pillar (210) on a substrate (SS), a vertical channel layer (230) surrounding the core pillar (210), an insulating layer (240) surrounding the vertical channel layer (230), and a body contact layer (220) formed between the core pillar (210) and the vertical channel layer (230) for dissipating floating charges in the vertical channel layer (230).

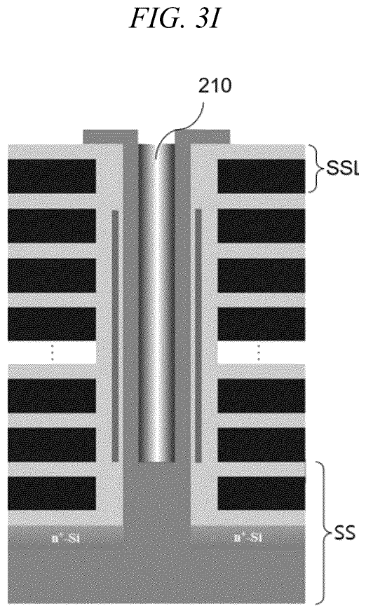

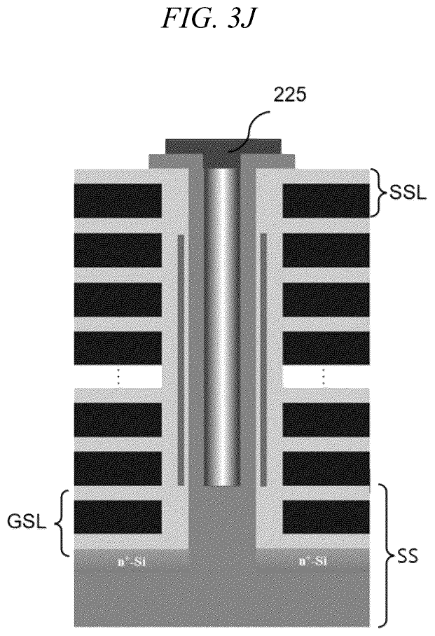

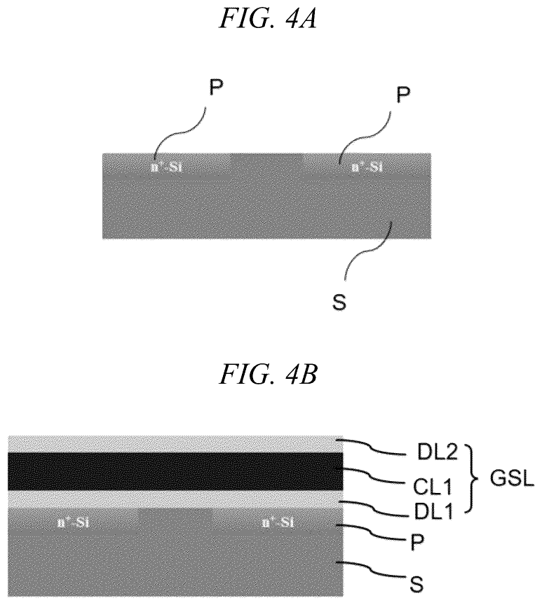

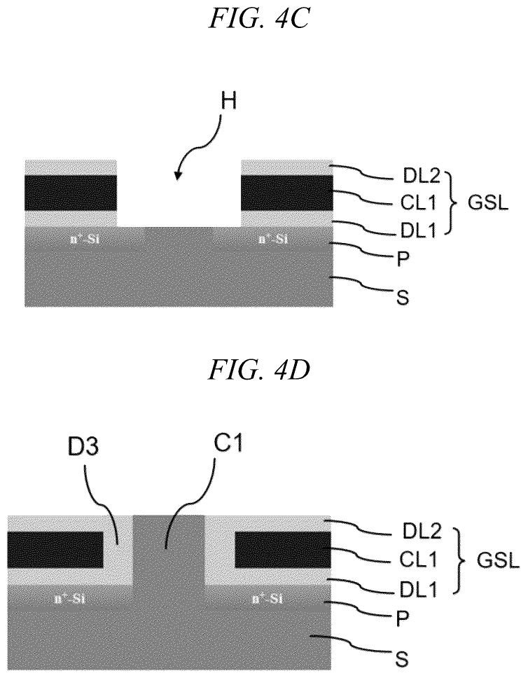

The substrate SS may be a non-limiting impurity doped poly-silicon substrate having transistor cells for the ground select line (GSL). The impurities may be p-type or n-type impurities (e.g., acceptor, donor). A description of the substrate SS may be found with reference to the description of FIGS. 4A through 4D hereinafter. The core pillar (210) may comprise an oxide. The vertical channel layer (230) is connected in a perpendicular direction to the channel region of the transistor cell (GSL) and may include polysilicon.

In one embodiment, the insulating layer (240) has an oxide-nitride-oxide (ONO) structure comprising a tunneling oxide layer (241), a charge trap layer (242), and a blocking oxide layer (243). The tunneling oxide layer (241) serves to tunnel electrons, and the charge trap layer (242) is a floating gate defined as a space where charge is stored, and may be composed of poly silicon to store the charge. The blocking oxide layer (243) may comprise an oxide film, e.g., a metal oxide film, and acts to prevent the charge stored in the charge trap layer (242) from escaping. The plurality of control gates (250) may be electrically isolated from each other by interlayer insulating layers (DL1, DL2, DL3, DL4), to be described later, and may supply a corresponding bias voltage to a select memory cell or a non-select memory cell during a program, data write, data erase, or data read operation. The control gate (250) may include a conductive metallic material.

The body contact layer (220) may be formed on an inner wall or sidewall of the vertical channel layer (230). Further, the body contact layer (220) may include a metal or conductive semiconductor material having a work function in an acceptable range, and the work function in the acceptable range may be greater than or equal to 4.6 eV. The metals having a work function of 4.6 eV or greater are titanium (Ti), copper (Cu), nickel (Ni), silver (Ag), molybdenum (Mo), osmium (Os), rhenium (Re), selenium (Se), tantalum (Ta), beryllium (Be), rhodium (Rh), and zinc (Zn), Cobalt (Co), Iron (Fe), Niobium (Nb), Tellurium (Te), Gold (Au), Iridium (Ir), Platinum (Pt), Antimony (Sb), Tungsten (W), and any one or more of their alloys or nitrides. In another embodiment, the conductive semiconductor material is a trivalent impurity doped semiconductor material, wherein the trivalent impurity doped semiconductor material may be p-type silicon. The p-type silicon may have any one of a monocrystalline, polycrystalline, or amorphous structure. The body contact layer (220) may function to maximize the boosting effect by effectively dissipating charges that accumulate in the corresponding cell channels by unwanted band-to-band tunneling or trap-assisted tunneling, which effectively prevents self-boosting behavior for cells present on non-selected bit lines when a program voltage is applied to those word lines during program operation.

The floating charges in the vertical channel layer (230) may be charges stored in the floating gate by the program voltage and released into the vertical channel layer (230) via tunneling. Additionally, the body contact layer (220) may dissipate the charge that accumulates on the underside of the non-selected memory cells by self-boosting.

Optionally, the core pillar (210) may further include a conductive pad (225) that covers the top exposed surface of the core pillar (210) and is in electrical communication with the body contact layer (220). The conductive pad (225) may have a first end that is connected to an end of the body contact layer (220) and fills a hole located above the core pillar (210) where the core pillar (210) is not present, and a second end that is equal to or greater than the width of the first end and is exposed to the exterior of the 3D non-volatile memory device (10) to provide a contact area. In addition, a bias voltage may be supplied through the conductive pad (225) during a data write, data erase, or data read operation of the 3D non-volatile memory device (10), as shown in Table 1 below.

TABLE 1

| | Program | Read | Erase |
|---|---|---|---|
| Selected BL | GND | (+) voltage | Floating or |
| (bit line) | | | (+) voltage |
| Unselected BL | V_{CC} | GND | Floating |
| SSL(string | V_{CC} | (+) voltage (SSL | Floating |
| select line) | | turn-on voltage) | |
| Selected WL | Program voltage | Read voltage | GND or (−) |
| (word line) | | | voltage |
| Unselected WL | Program pass | Read pass Voltage | GND or (−) |
| | Voltage | | voltage |
| Body Contact | GND | GND, (−) voltage, | Erase voltage |
| Layer (220) | | or floating | |

Notably, during read operation, it is important that current only flows into the channel of the bit line and not into the body. Therefore, it may be beneficial to reverse-bias between the body and the channel, or at least apply body biasing to ensure that an energy barrier is maintained from the channel to the body.

As a result, a negative voltage or GND may be applied to the body contact layer (220) during a read operation to allow channel electrons to flow to the BL end by the (+) voltage, or to float the electrons. In Table 1, the program pass voltage of the unselected WL is the Vₚₐₛₛ voltage applied during self-boosting, and the read pass voltage is the voltage that allows the cells that share a bit line with the cell to be read to turn on regardless of the Program/Erase state, and the read pass voltage has a different purpose than the Vₚₐₛₛ voltage applied during self-boosting. However, the bias voltage supply of Table 1 above may be changed in the memory design, and the present disclosure is not limited to the bias voltage supply of Table 1 above.

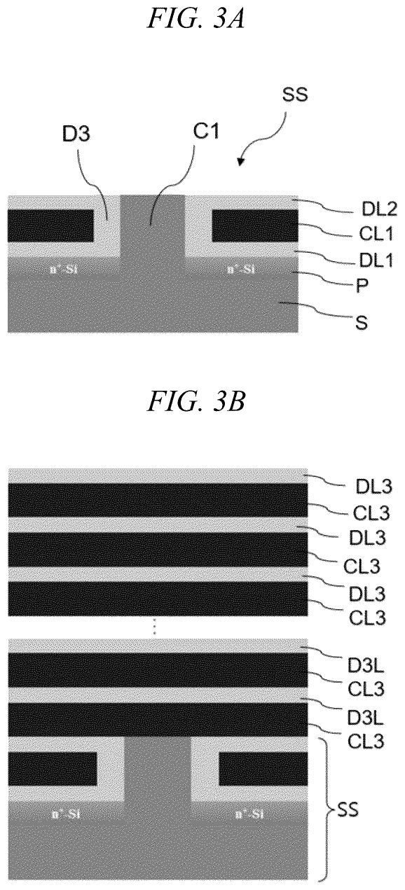

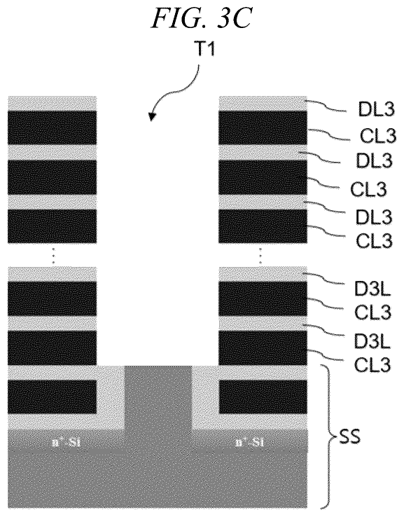

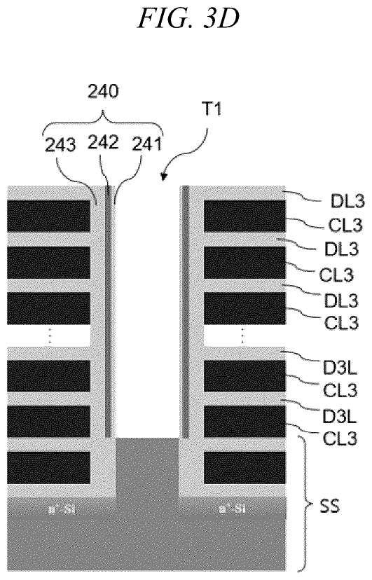

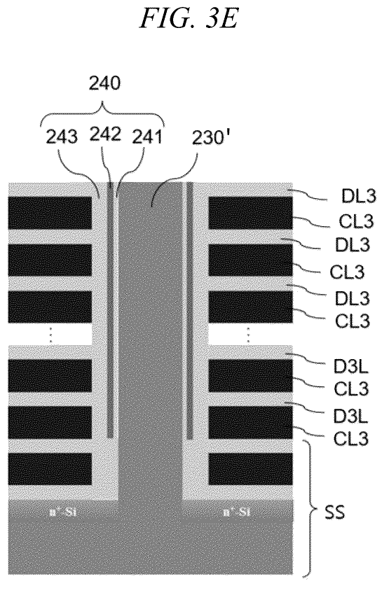

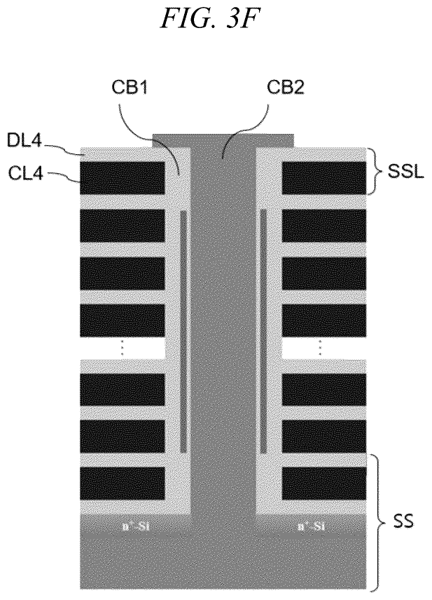

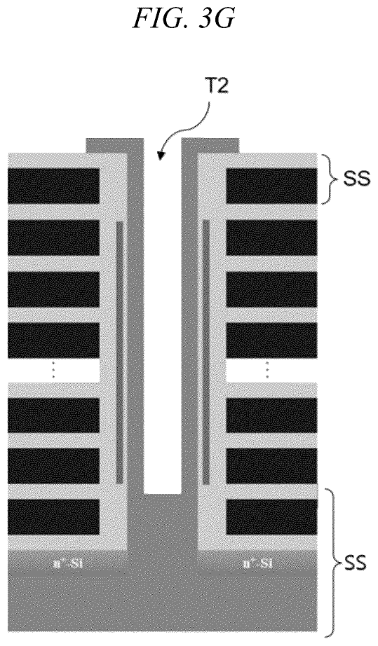

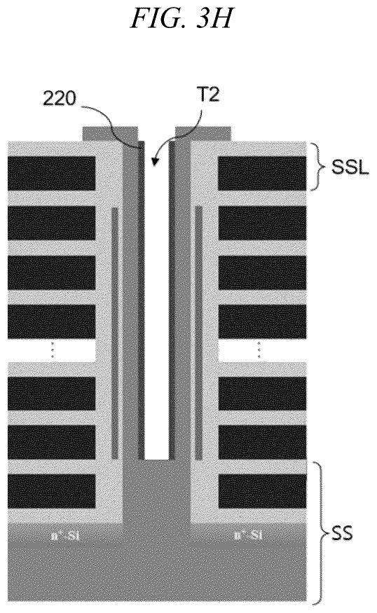

FIGS. 3A through 3J are sequential cross-sectional views illustrating a method of fabricating a 3D non-volatile memory device according to one embodiment of the present disclosure.

Referring to FIGS. 3A to 3J, a method of fabricating a 3D non-volatile memory device includes the steps of providing a substrate (SS) (FIG. 3A), alternately and repeatedly stacking an interlayer insulating film (DL3) and an interlayer conductive film (CL3) on the substrate (SS) (FIG. 3B), forming a first trench (T1) vertically penetrating the repeatedly stacked interlayer insulating film (DL3) and interlayer conductive film (CL3) (FIG. 3C), and forming an insulating layer (240) for storing information on an inner sidewall of the first trench (T1) (FIG. 3D), filling the interior of the first trench (T1) with channel material to form a vertical channel pillar (230′) so that the insulating layer (240) is not exposed (FIGS. 3E, 3F); and forming a second trench (T2) smaller than the first trench (T1) in the vertical channel pillar (230′) to form a vertical channel layer (230) (FIG. 3G), forming a body contact layer (220) on the sides of the vertical channel layer (230) (FIG. 3H), and filling the second trench (T2) with core material to form the core pillar (210) (FIG. 3I).

In a non-limiting example, the substrate (SS) of FIG. 3A may include a p-type poly-silicon substrate S and transistor cells for a ground select line (GSL). Alternatively, the substrate SS may include an n-type poly-silicon substrate S with transistor cells for the Ground Select Line (GSL). For a detailed description of the steps of preparing the substrate SS (FIG. 3A), reference may be made to FIGS. 4A to 4D below.

In FIG. 3B, the number of repeated stacks of the interlayer insulating film (DL3) and the interlayer conductive film (CL3) may be determined by considering the number of memory cells, select transistors, and ground transistors. In one embodiment, the interlayer insulating film (DL3) may be silicon oxide (SiO₂). The interlayer conductive film (CL3) may comprise a conductive metallic material and may act as a control gate.

While FIG. 3C illustrates one first trench (T1) to form one bit line, it is preferred to form N first trenches to form N non-limiting bit lines (BLi, BL2, BL3, . . . , BLn) by the same etching process. Further, the width (ti) of the first trench (T1) may be determined by considering the thickness of the insulator (240), channel layer (230), and body contact layer (220) to be subsequently formed, and the first trench (T1) passes through the center of the pillar structure shown in FIG. 3C. The first trench (Ti) may have a flat plate or cylindrical shape having a uniform thickness, but the present disclosure is not limited thereto. The first trench T1 may be referred to as a hole, an opening, or a cylindrical opening.

In FIG. 3D, the steps of forming the insulating layer (240) may include first depositing an insulating layer (non-limitingly SiO₂, for example) that serves as a blocking oxide layer (243) for each memory cell, forming a charge trap layer (242) on the blocking oxide layer (243), and forming a tunneling oxide layer (241) on the charge trap layer (242). The blocking oxide layer (243) may be deposited relatively thick, e.g., thicker than the tunneling oxide layer (241) and thicker than the charge trap layer (242), to provide complete isolation between the charge trap layer (242) and the control gates (CL3) of the memory cell. The thickness of the tunneling oxide layer (241), which may include the same kind of insulating material as the blocking oxide layer (243), may be deposited relatively thinner than the thickness of the blocking oxide layer (243) so that tunneling occurs in response to a program voltage or an erase voltage between the charge trap layer (242) and the channel layer (230). Further, the charge trap layer (242) may be made of silicon nitride (SiN), as a non-limiting example. After forming the blocking oxide layer (243), the charge trap layer (242), and the tunneling oxide layer (241), respectively, an additional process of hole formation may be performed. For example, after depositing each layer, a vertical anisotropic etch process may be performed to remove material from the base of the first trench T1, and possibly to remove material from the upper surface of the interlayer insulating film (DL3). After depositing the blocking oxide layer (243), hole forming (e.g., anisotropic etching) may be performed before depositing the charge trap layer (242), and after depositing the charge trap layer (242), hole forming (e.g., anisotropic etching) may be performed before depositing the tunneling oxide layer (241), and after depositing the tunneling oxide layer (241), hole forming (e.g., anisotropic etching) may be performed to clean the base of the first trench T1 before forming the channel pillar.

In FIG. 3E, the first trench T1 in which the insulating layer (240) is deposited may be filled with a semiconductor material to form a vertical channel pillar (230′). The semiconductor material may comprise poly-silicon, which may have a suitable conductive type or may be undoped poly-silicon, depending on whether the non-volatile memory device is a Bit Cost Scalable (BICS), Vertical Recess Array Transistor (VRAT), or Terabit Cell Array Transistor (TCAT) structure. In other embodiments, the channel lines may be compound semiconductors, carbon-based materials, polymeric materials, or other suitable channeling materials other than single crystal silicon or traditional silicon materials. Preferably, in the present disclosure, the material of the vertical channel pillars (230′) may comprise p-type polysilicon, which is the same as the material of the channel region (C1) of the substrate (SS) or GSL transistor (GSL).

In one embodiment, the step of forming the vertical channel pillar (230′) (FIG. 3F) may further comprise forming a transistor cell for the source select line (SSL). First, to form the SSL transistor cell, an interlayer insulating film (DL4) and an interlayer conductive film (CL4) are stacked at least once on the top end of the memory cell, and then holes for channel formation are formed. The interlayer conductive film (CL4) serves as the gate of the SSL transistor and may be the same as the gate material of the GSL transistor described above or the material of the interlayer conductive film (CL3). Then, an insulating film (CB1) may be formed on the inner wall of the hole, and the hole in which the insulating film (CB1) (e.g., SiO₂) is formed may be filled with a semiconductor material to form a channel region (CB2). At this time, the upper portion of the channel region of the SSL transistor cell may be partially exposed, and a portion of the material of the channel region (CB2) may extend beyond the central pillar to cover a portion of the insulating film (CB1). In a non-limiting example, the material of the channel region (CB2) of the SSL transistor cell may be the same p-type polysilicon as the substrate (SS) and the channel region (C1) of the GSL transistor, and the channel region (230′) of the memory cell. Further, the channel region (CB2) of the SSL transistor cell, the channel region (C1) of the GSL transistor, and the channel region (230′) of the memory cell are electrically conductive and may form a continuous conductive structure.

Next, as shown in FIG. 3H, the channel region (230′) is etched to form a trench (T2), which may be a cylindrical opening or hole. The body contact layer (220) formed over the inner wall of the second trench (T2) formed in FIG. 3G, or on the sidewalls of the channel layer (230), may be deposited by any one of chemical vapor deposition (CVD), atomic layer deposition (ALD), and physical vapor deposition (PVD), which are capable of conformal deposition in a high aspect ratio hole structure. Alternatively, an epitaxy process capable of in-situ doping may be utilized. The body contact layer (220) may comprise a metal or conductive semiconductor material having a workfunction in an acceptable range. The body contact layer (220) may be made of titanium (Ti), copper (Cu), nickel (Ni), silver (Ag), molybdenum (Mo), osmium (Os), rhenium (Re), selenium (Se), tantalum (Ta), beryllium (Be), rhodium (Rh), zinc (Zn), cobalt (Co), iron (Fe), niobium (Nb), tellurium (Te), gold (Au), iridium (Ir), platinum (Pt), antimony (Sb), tungsten (W), and any one or more of alloys or nitrides thereof. Alternatively, the body contact layer (220) may comprise p-type silicon (monocrystalline, polycrystalline, or amorphous silicon) where the trivalent impurity doped semiconductor material may be p-type silicon. If the body contact layer (220) is p-type polysilicon, an epitaxy process capable of in-situ doping may be performed to minimize unwanted dopant diffusion into the channel region.

In FIG. 3I, the core material of core pillar (210) is deposited to fill the second trench (T2) where the body contact layer (220) is formed, and the core material may be an oxide. Preferably, the core material may be a silicon oxide. In anon-limiting embodiment, trench (T2) may be filled with a material of the body contact layer (220) instead of an oxide. Furthermore, it is necessary to deposit the body contact layer (220) to have a thickness sufficient to form the core pillar (210) inside the second trench (T2).

Optionally, the method may further include the step of forming a conductive pad (225) (FIG. 3J) that covers the top exposed surface of the core pillar (210) and is in electrical communication with the body contact layer (220). Specifically, the conductive material fills a hole in body contact layer (220) present above the core pillar (210) and partially covers the upper surface of the exposed channel layer (230) to enable contact. In some embodiments, the conductive pads (225) may contact the contact regions of the bit lines and adjacent conductive pads (225).

In some embodiments, after forming the core pillar (210), etching may be performed to expose a portion of the upper inner wall of the body contact layer (220), and the upper portion of the exposed body contact layer (220) may be covered with a conductive material. The body contact layer (220) and the conductive pad (225) may be the same conductive material. In some embodiments, the body contact layer (220) and the conductive pad (225) may use different conductive materials, taking into account dry etchability and resistivity reduction.

On the other hand, the conductive pad (225) may be supplied with different bias voltages in conjunction with the control gate of the memory cell, the gate of the SSL transistor, and the gate of the GSL transistor during a data write, data erase, or data read operation of the 3D non-volatile memory device. Specifically, during a data write operation, a GND signal may be applied to both the bit line and the conductive pad (225), or during a data erase operation, the bit line may be open or floating and a program voltage may be applied to the conductive pad (225). Also, in a data read operation, a read voltage is applied to the bit line and a 0 V or negative voltage is applied to the conductive pad (225). At this time, the channel and the body contact layer (220) are isolated, so that no current flows directly between the bit line and the body contact layer (220).

FIGS. 4A through 4D are cross-sectional views sequentially illustrating a method of preparing a substrate SS for a 3D non-volatile memory device according to one embodiment of the present disclosure.

First, in FIG. 4A, a p-type polysilicon substrate S is prepared, and N-type impurities are ion implanted to form a source region P on the p-type polysilicon substrate S. Then, in FIG. 4B, an insulating layer (DL1) may be deposited on the p-type polysilicon substrate S to insulate the source region P, a conductive layer (CL1) may be deposited on the insulating layer (DL1), and another insulating film (DL2) may be deposited on the conductive layer (CL1). The insulating films (DL1), (DL2) may be SiO₂. The conductive layer (CL1) for forming the gate of the GSL transistor may be formed over the substrate S on which the insulating film (DL1) is formed. In an embodiment, the conductive layer (CL1) may be an impurity-doped (or conductive) polysilicon or a conductive metal. The insulating film (DL2) may be deposited to separate the conductive layer (CL1) of the GSL transistor from the conductive layer (CL3) to be deposited on top of the insulating film (DL2) as discussed above with respect to FIG. 3B.

Then, in FIG. 4C, the conductive layer (CL1) and the insulating layers (DL1), (DL2) in the region where the channel of the GSL transistor is to be formed are etched to form a hole H. At this time, the hole H has a width such that the first part of the source region P is exposed.

Then, in FIG. 4D, the gate insulating film (D3) of the GSL transistor is deposited. In an embodiment, the gate insulating film (D3) may be SiO₂. As the exposed source region P is covered by the gate insulating film (D3), the width of the hole H before depositing the gate insulating film (D3) may become smaller. The channel material may then be filled inside the reduced hole H to form the channel region (C1) of the GSL transistor. In an embodiment, the material of the channel region (C1) may include p-type polysilicon, which may be the same material as the substrate S.

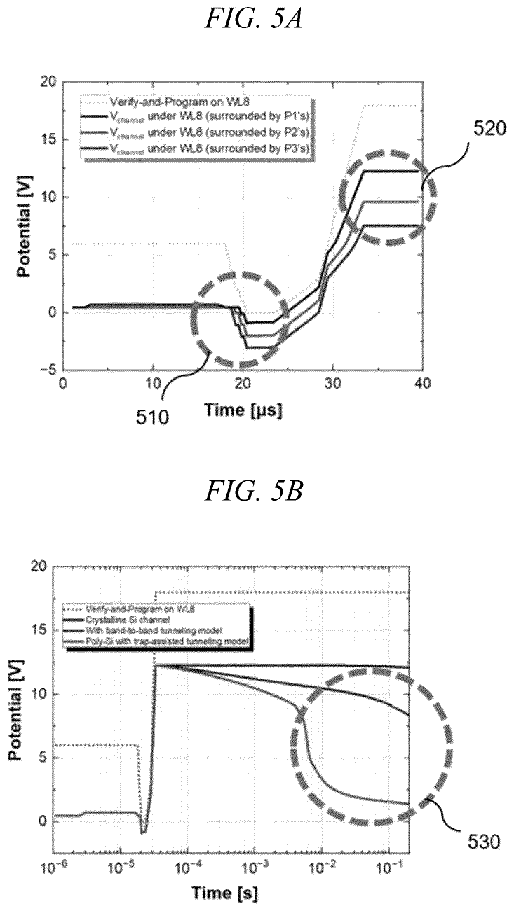

FIGS. 5A and 5B are graphs to illustrate the performance of a 3D non-volatile memory device according to one embodiment of the present disclosure. FIG. 5A is a graph showing the change in potential [V] over time in the absence of body contact for a selected memory cell and a cell on an unselected BL while sharing (WL8), and for neighboring cells having states P1, P2, and P3 while sharing BL, Crystalline Si channel, Poly-Si channel based on a band to band model with band-to-band tunneling model, and Poly-Si channel based on a trap-assisted tunneling model with a trap-assisted tunneling model for the memory cell (WL8) in the absence of body contact.

In the aforementioned 3D non-volatile memory device formed between the core pillar (210) and the vertical channel layer (230), in the absence of a body contact layer (220) to dissipate the floating charge of the vertical channel layer, i.e., in the situation of FIG. 5A, during read/verify, the unselected cells (P1, P2, P3) generate a negative channel potential (510), and the larger the negative channel potential, the lower the potential [V] at which boosting begins, resulting in unstable self-boosting (520).

Referring to FIG. 5B, even after boosting, a voltage potential drop may occur due to the inability to effectively dissipate the rapidly accumulating charge by tunneling (530). This may result in a program inhibit fail, which may result in a data write inhibit fail.

All of these problems are caused by the channel being in a floating state, and to solve these problems, the present disclosure introduces a body contact layer (220) disposed between the core pillar (210) and the vertical channel layer (230) to dissipate the floating charge of the vertical channel layer.

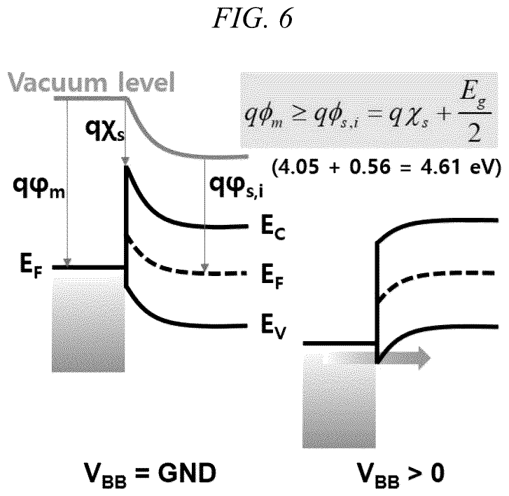

FIG. 6 is a drawing to illustrate the bonding between the body contact layer and the vertical channel layer according to one embodiment of the present disclosure.

Referring to FIG. 6, E_{F}is the Fermi energy, E_{C} is the conduction band, and E_{V} is the valence band. qφₘ is the work function of the body contact layer, qφ_{s,i} is the work function of the vertical channel layer, and qχₛ is is the electron affinity of the vertical channel layer. The relationship between them may be defined as [Equation 1].

$$q {ϕ}_{m} \geq q {ϕ}_{s , i} = q {χ}_{s} + \frac{{E}_{g}}{2} . \qquad [ Equation 1 ]$$

In FIG. 6, 4.05 eV (affinity of semiconductor silicon)+0.56 eV (bandgap energy of semiconductor silicon (E_{g})/2)=4.61 eV

The range of possible work functions of the metals that may be used as the body contact layer (220) in the present disclosure may be tailored to achieve certain characteristics. To this end, the following characteristics should be considered.

First, it should be capable of generating only a sufficient vertical electric field inside the channel region during a data write (program) operation. It is also desirable that the energy band in the silicon region remains flat or rightward bending when the ground (GND) voltage is applied.

Second, during data read/verify operation, it is advantageous to isolate the channel so that current may only flow between bit line and string GND when V_{BB}=GND. Similar to the data write (program) operation, it is desirable that the energy bands in the silicon region remain flat or rightward bending when the GND voltage is applied.

Third, during the data recovery operation after read/verify, it is advantageous to prevent local isolation of non-selected cells by effectively introducing holes from the body into the channel.

Fourth, it is advantageous to effectively release the electrons emitted into the channel during the data erase operation, that is, the electrons stored in the charge trap layer (242) or the floating gate are transferred to the channel during the erase operation, and the electrons transferred to the channel are effectively released.

Fifth, hole injection should rapidly dissipate in real time the electrons that accumulate in cell channels on non-selected bit lines that share a selected word line due to tunneling that occurs during self-boosting behavior. Electrons by drift and diffusion may be dissipated by leakage into the body or recombination.

The junction between the body contact layer (220) and the vertical channel layer (230) has ohmic and Schottky contact from the electron perspective and ohmic and Schottky contact from the hole perspective.

The above characteristics may be satisfied when the metal workfunction is located close to the valence band of the channel silicon, which is desirable for the operation of the 3D non-volatile memory device 10. Specifically, the range of the metal work function should be 4.61 eV (=4.05 eV+0.56 eV) or more, and may include Ti/Ni alloys, Ni, TiN, Cu, and the like.

On the other hand, the work function of p-type silicon is also included in the range of work functions of the acceptable metals described above. For example, the work function of p-type silicon is approximately 5.17 eV (=4.05 eV+1.12 eV), which satisfies the acceptable work function range of 4.61 eV or more. At this point, low-temperature doping techniques may be used to deposit p-type silicon onto the channel lining. Specifically, p-type doped ALD, two-step low-pressure chemical vapor deposition (LPCVD) (intrinsic+in-situ boron doping) may be used to thicken the channel and then fill the core pillars with p-type silicon to obtain a margin value that allows for acceptor diffusion into the channel region.

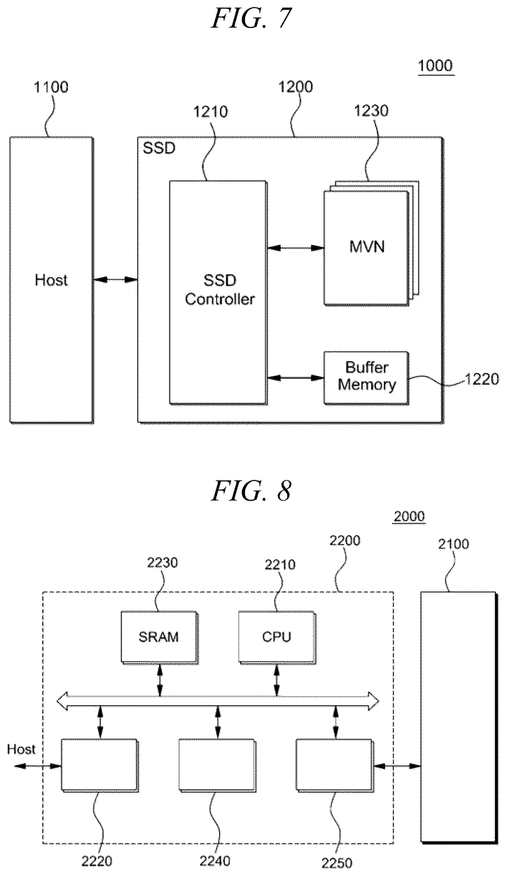

FIG. 7 is a block diagram illustrating a storage device (1000) including a solid-state disk (hereinafter, SSD), according to one embodiment of the present disclosure.

Referring to FIG. 7, storage device (1000) includes a host (1100) and an SSD (1200). The SSD (1200) may include an SSD controller (1210), buffer memory (1220), and non-volatile memory elements (1230). The SSD controller (1210) provides electrical and physical connectivity between the host (1100) and the SSD (1200). In one embodiment, the SSD controller (1210) provides interfacing with the SSD (1200) in a bus format corresponding to the bus format of the host (1100). Additionally, the SSD controller (1210) may decode instructions provided by the host (1100) and access the non-volatile memory device (1230) based on the decoded results. Non-limiting examples of bus formats of the host (1100) may include Universal Serial Bus (USB), Small Computer System Interface (SCSI), PCI express, Advanced Technology Attachment (ATA), Parallel ATA (PATA), Serial ATA (SATA), and Serial Attached SCSI (SAS).

Buffer memory (1220) may temporarily store write data from host (1100) or data read from non-volatile memory element (1230). If the data present in the non-volatile memory element (1230) is cached at the time of a read request from the host (1100), the buffer memory (1220) may be provided with a cache function to provide the cached data directly to the host (1100). In general, the data transfer rate by the bus format (e.g., SATA or SAS) of the host (1100) may be faster than the transfer rate of the memory channels of the SSD (1200). In this case, a large amount of buffer memory (1220) may be provided to minimize the performance degradation caused by the speed difference. The buffer memory (1220) for this purpose may be, but is not limited to, synchronous DRAM to provide sufficient buffering.

Non-volatile memory elements (1230) may be provided as storage media in SSD (1200). For example, the non-volatile memory element (1230) may be a NAND-type Flash memory having a large storage capacity in accordance with the aforementioned embodiments. In another example, the non-volatile memory element (1230) may be a memory system that includes a mix of NOR flash memory, phase change memory, magnetic memory, resistive memory, ferroelectric memory, or a heterogeneous mix of memory devices selected from the foregoing.

FIG. 8 is a block diagram illustrating a memory system (2000) according to another embodiment of the present disclosure.

Referring to FIG. 8, a memory system (2000) according to the present disclosure may include a memory controller (2200) and a flash memory element (2100). The flash memory element (2100) may include any of the non-volatile memory elements described above. The flash memory element (2100) may detect memory cells with abnormal speeds when verifying target states, allowing for high-speed, reliable program performance.

A memory controller (2200) may be configured to control the flash memory elements (2100). SRAM (2230) may be used as operational memory for CPU (2210). The host interface (2220) may implement a data exchange protocol for a host to interface with the memory system (2000). Error correction circuitry (2240) provided in the memory controller (2200) may detect and correct errors contained in data read from the flash memory (2100). A memory interface (2260) may interface with the flash memory (2100) of the present disclosure. The CPU (2210) may perform various control operations for exchanging data with the memory controller (2200). The memory system (2000) according to the present disclosure may further include a ROM (not shown) storing code data for interfacing with a host.

The memory controller (2200) may be configured to communicate with external circuits (e.g., a host) through any one of various interface protocols such as USB, MMC, PCI-E, SAS, SATA, PATA, SCSI, ESDI, or IDE. The memory system (2000) according to the present disclosure is suitable for use in computers, portable computers, UMPCs (Ultra Mobile PCs), workstations, netbooks, PDAs, portable computers, web tablets, wireless phones, mobile phones, smartphones, digital cameras, digital audio recorders, digital audio players, digital picture recorders, digital picture players, digital video recorders, digital video players, devices capable of transmitting and receiving information in a wireless environment, and various user devices such as home networks.

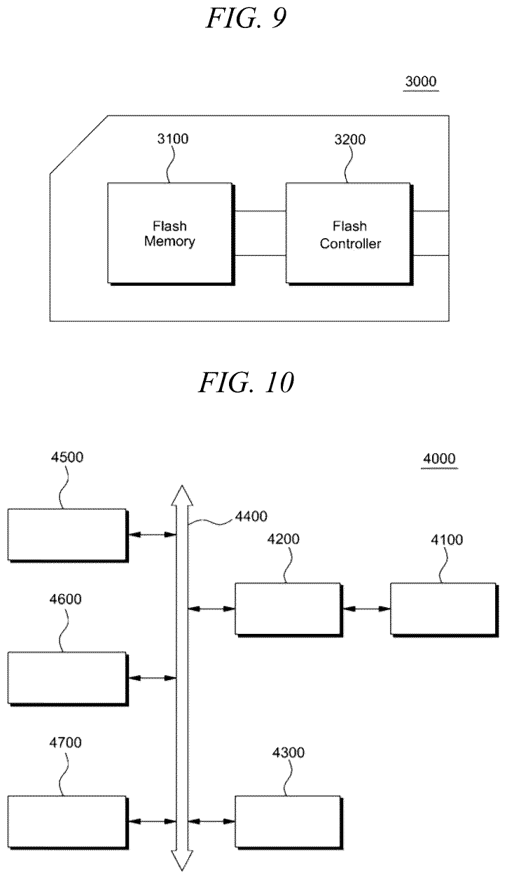

FIG. 9 is a block diagram illustrating a data storage device (3000) according to another embodiment of the present disclosure.

Referring to FIG. 9, a data storage device (3000) according to the present disclosure may include a flash memory (3100) and a flash controller (3200). The flash controller (3200) may control the flash memory (3100) based on control signals received from external circuitry of the data storage device (3000). The three-dimensional memory array structure of the flash memory (3100) may be, for example, a channel stacked structure, a straight-shaped Bit Cost Scalable structure, and a pipe-shaped Bit Cost Scalable structure, wherein the structures are exemplary and not limiting to the present disclosure.

The data storage device (3000) of the present disclosure may comprise a memory card device, an SSD device, a multimedia card device, an SD card, a memory stick device, a hard disk drive device, a hybrid drive device, or a universal serial bus flash device. For example, the data storage device (3000) of the present disclosure may be a memory card that meets standards or specifications for use in electronic devices such as digital camera and personal computers.

FIG. 10 is a block diagram illustrating a flash memory device (4100) and a computing system (4000) including it, according to one embodiment of the present disclosure.

Referring to FIG. 10, a computing system (4000) according to the present disclosure may include a flash memory device (4100) electrically connected to a bus (4400), a memory controller (4200), a modem (4300) such as a baseband chipset, a microprocessor (4500), and a user interface (4600).

The flash memory device (4100) shown in FIG. 10 may be any of the non-volatile memory devices described above. The computing system (4000) according to the present disclosure may be a mobile device, in which case a battery (4700) may be further provided to provide an operating voltage for the computing system (4000). Although not shown, the computing system according to the disclosure may further be provided with an application chipset, a Camera Image Sensor (CIS) Processor, or mobile RAM. The memory controller (4200) and flash memory device (4100) may form, for example, a solid-state drive/disk (SSD) using non-volatile memory elements to store data.

The non-volatile memory devices and/or memory controllers according to the present disclosure may be mounted using various types of packages. For example, the flash memory device and/or memory controller according to the present disclosure may be mounted in a package on package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), System In Package (SIP), Multi Chip Package (MCP), Wafer-level Fabricated Package (WFP), or Wafer-Level Processed Stack Package (WSP).

According to the embodiments of the present disclosure described above, it is possible to implement 3D non-volatile memory devices that may address self-boosting and tunneling-induced potential drops from unselected cells. Furthermore, the technical challenges of the present disclosure may prevent the memory operation of the 3D non-volatile memory device from being in a floating state, thereby improving the reliability of operations.

Preferred embodiments of the present disclosure have been disclosed herein, and although certain terms are used, they are used in a general sense only to facilitate the description and understanding of the disclosure and are not intended to limit the scope of the disclosure. In addition to the embodiments disclosed herein, other modifications based on the technical ideas of the present disclosure will be apparent to those of ordinary skill in the art to which the present disclosure belongs. One having ordinary knowledge in the art will recognize that the 3D non-volatile memory device and the method of manufacturing the same according to the embodiments described with reference to FIGS. 2A through 4D may be subject to various substitutions, changes, and modifications without departing from the technical ideas of the disclosure. The scope of the disclosure is therefore not to be limited by the embodiments described, but by the technical ideas recited in the claims.

What is claimed is:

1. A 3D non-volatile memory device, comprising:
a vertically elongated core pillar over a substrate;
a vertical channel layer surrounding the core pillar;
an insulating layer surrounding the vertical channel layer; and
a body contact layer formed between the core pillar and the vertical channel layer, and configured to dissipate a floating charge of the vertical channel layer.

2. The memory device of claim 1, wherein the body contact layer is formed on an inner wall of the vertical channel layer.

3. The memory device of claim 1, wherein the body contact layer comprises a metal or a conductive semiconductor material having a work function greater than or equal to a work function of the vertical channel layer.

4. The memory device of claim 3, wherein the work function of the body contact layer is greater than or equal to 4.6 eV.

5. The memory device of claim 3, wherein the metal is at least one selected from the group consisting of titanium (Ti), copper (Cu), nickel (Ni), silver (Ag), molybdenum (Mo), osmium (Os), rhenium (Re), selenium (Se), tantalum (Ta), beryllium (Be), rhodium (Rh), zinc (Zn), cobalt (Co), iron (Fe), niobium (Nb), tellurium (Te), gold (Au), iridium (Ir), platinum (Pt), antimony (Sb), tungsten (W), and any one or more of their alloys or nitrides.

6. The memory device of claim 3, wherein the conductive semiconductor material is a semiconductor material doped with trivalent impurities.

7. The memory device of claim 6, wherein the trivalent impurity doped semiconductor material is p-type silicon.

8. The memory device of claim 7, wherein the p-type silicon has any one of a monocrystalline, polycrystalline, or amorphous structure.

9. The memory device of claim 1, wherein the floating charge in the vertical channel layer is a charge stored in a floating gate by a program voltage and released into the vertical channel layer via tunneling.

10. The memory device of claim 1, wherein the body contact layer is configured to dissipate charges accumulating in the vertical channel by band-to-band tunneling or trap-assisted tunneling, which prevents self-boosting behavior for memory cells coupled to non-selected bit lines when a program voltage is applied to word lines during a program operation.

11. The memory device of claim 1, further comprising:
a conductive pad covering an upper exposed surface of the core pillar and electrically conducting with the body contact layer.

12. The memory device of claim 11, wherein the conductive pad is configured to supply different bias voltages during a data write, data erase, or data read operation of the 3D non-volatile memory device.

13. A method of manufacturing a 3D non-volatile memory device, comprising:
forming a film stack by alternately forming a plurality of interlayer insulating film layers and a plurality of conductive film layers over a substrate;
forming a first opening vertically penetrating the film stack;
forming an insulating layer for storing information on an inner sidewall of the first opening;
forming a vertical channel pillar by filling the first opening with a material constituting a channel region so that the insulating layer is not exposed;
forming a second opening smaller than the first opening in the vertical channel pillar to form a vertical channel layer;
forming a body contact layer on an exposed surface of the vertical channel layer; and
filling the second opening with a core material to form a core pillar.

14. The method of claim 13, further comprising:
forming a conductive pad covering an upper exposed surface of the core pillar and electrically coupled with the body contact layer.

15. The method of claim 14,
wherein forming the conductive pad comprises:
filling a hole in the body contact layer and above the core pillar with a conductive material.

16. The method of claim 14, wherein a first end face of the conductive pad is in contact with a first end face of the body contact layer and a second end face of the conductive pad is exposed to provide a contact region.

17. The method of claim 13, wherein the body contact layer is at least one selected from the group consisting of titanium (Ti), copper (Cu), nickel (Ni), silver (Ag), molybdenum (Mo), osmium (Os), rhenium (Re), selenium (Se), tantalum (Ta), beryllium (Be), rhodium (Rh), zinc (Zn), cobalt (Co), iron (Fe), niobium (Nb), tellurium (Te), gold (Au), iridium (Ir), platinum (Pt), antimony (Sb), tungsten (W), and any one or more of their alloys or nitrides.

18. The method of claim 13, wherein the body contact layer comprises p-type silicon.

19. The method of claim 13, wherein forming the body contact layer on the exposed surface of the channel layer comprises one of a conformal deposition process and an epitaxy process capable of in-situ doping.

20. The method of claim 13, wherein the vertical channel layer is coupled to the substrate.
